(19) United States
(12) Patent Application Publication
(10) Pub. No.: US 2007/0166630 A1
(43) Pub. Date: Jul. 19, 2007

(54) Photomasks including multi-layered light-shielding and methods of manufacturing the same

(75) Inventors: Chang-Hwan Kim, Suwon-si (KR); Suk-Ho Lee, Hwaseong-si (KR); Young-Soo An, Yongin-si (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 11/649,775

(22) Filed: Jan. 5, 2007

(30) Foreign Application Priority Data
Jan. 13, 2006 (KR) 10-2006-0004117

(51) Int. Cl. B32B 9/00; B32B 17/06; B32B 17/10; G03C 5/00; G03F 1/00

(52) U.S. Cl. 430/5; 428/428; 428/430; 430/322; 430/394

(57) ABSTRACT

Example embodiments may provide photomasks including multi-layered light-shielding, and methods of manufacturing the same. An example embodiment may include a transparent substrate, and a multi-layered light-shielding layer having non-transparent and transparent layers alternately laminated on the transparent substrate.

### PRIORITY STATEMENT

This application claims priority under 35 U.S.C. § 119 to Korean Patent Application No. 10-2006-0004117 filed on Jan. 13, 2006 in the Korean Intellectual Property Office (KIPO), the entire disclosure of which is incorporated herein by reference.

### BACKGROUND

Example embodiments relate to photomasks that may be used in semiconductor manufacturing and methods of manufacturing the same. For example, example embodiments may relate to photomasks including multi-layered light-shielding (both blank and patterned multi-layered light-shielding) and methods of manufacturing the same.

### DESCRIPTION OF RELATED ART

With the development of semiconductor technologies, semiconductor devices (e.g., memory devices) are being developed more rapidly. For example, techniques for high-speed operation, low power consumption, increase in capacity, and reduction in size have been rapidly developed. Furthermore, techniques for improving integration have attracted attention.

In order to achieve the techniques for improving integration of semiconductor devices, circuit design techniques, materials, and various process techniques may need to be developed evenly and/or equally. Among the techniques of improving the integration of semiconductor devices, a patterning technique of forming minute unit devices, such as transistors, on wafers is important to improve the integration of semiconductor devices. The patterning technique may include photolithography and etching. In addition, the photolithography may include a technique of manufacturing a photomask and a technique of transferring patterns onto wafers using the photomask. According to the technique of manufacturing a photomask, the patterns to be transferred onto the wafers are formed on the photomask. In this example, the patterns need to be formed to have an accurate shape and a uniform size. Further, there may need to be no defects on a glass substrate and in the patterns. That is because light passes through the glass substrate and the glass substrate is sensitive to various defects.

In photomasks according to the related art, there are binary type photomasks, transmittance attenuating phase shift photomasks (hereinafter referred to as “PSM”), chromium-less PSMs (hereinafter referred to as “CPSM” or “Cr-less PSM”), and rim type PSMs. In binary type photomasks, non-transparent light-shielding patterns are formed on a glass substrate. Transmittance attenuating PSM adjust light transmittance to be several to tens % or less and inverts a phase of transmitted light by 180°. CPSM selectively etch a glass substrate with no transmittance attenuating patterns so as to allow light transmitting an etched region and light transmitting a non-etched region to have a phase difference of 180°. Rim type PSM have light-shielding patterns which are partially formed on a CPSM.

Because the photomasks discussed above have both merits and disadvantages, a photomask may be appropriately selected according to types of patterns to be formed. For example, binary type photomasks may be used to form non-minute patterns because they are easily manufactured and have low manufacturing costs, but provide low patterning resolution. Transmittance attenuating PSMs may be used to form contacts or via patterns in spite being expensive and difficult to manufacture, because they provide high patterning resolution. CPSM may be used to form line/space patterns, such as gates of minute logic devices, because they provide excellent resolution for the line/space patterns. Because the photomasks are used in a semiconductor manufacturing process, they need to be used continuously for a long time. That is, the photomasks need have good durability and a relatively long life-span.

In addition, the photomasks need to generate little defects. Because a photomask is used to successively transfer patterns to tens to millions of wafers, it may be impossible to test the photomask before every exposure. In order to test the photomask in use, a process must be interrupted so as to take the photomask out of the exposure equipment. A test process causes inconvenience and affects productivity due to the interruption of a production process. For example, a test process may include taking the photomask out of the exposure equipment, removal of a pellicle coupled to the photomask in order to protect the patterns, testing by an electron microscope, cleaning, coupling of the pellicle, insertion into the exposure equipment, and alignment. Therefore, preferably, generated detects need to be rare so as not to affect the production process in a harmful manner.

When semiconductor devices are manufactured using the photomasks according to the related art, a defect called haze may be generated on the patterns of the photomask. Haze is a progressive defect, that is, haze gradually increases over time. Therefore, the photomask needs to be cyclically tested, and the defect needs to be removed by a cleaning process after detection. If the defect is not removed, the shape of the haze is transferred to the wafers by photolithography. Therefore, the patterns may be not properly formed on the wafers.

Definite components and causes of the haze defect have not been clearly found. Because it may be observed through an electron microscope that haze gets reduced when an electron beam is irradiated onto the haze, it is believed that the haze defect is not merely a general physical defect. There have been various analyses and opinions about the haze defect. For example, it has been proposed that the haze defect occurs due to remnants that are not completely removed in a manufacturing process, or out gassing generated from the pellicle. However, there has not been provided a definite cause or solution for the haze defect. In addition, it has been expected that Mo/Si-based compound, which is used in transmittance attenuating PSMs, has a close relationship with haze because the haze frequently occurs in the transmittance attenuating PSMs.

### SUMMARY

Example embodiments may provide a technique of forming patterns on a photomask. For example, example embodiments may provide a photomask which has few defects, is relatively easy to manufacture, and provides good pattern resolution. This may include a method of manufacturing a photomask and a blank photomask.

According to example embodiments, a photomask may include a transparent substrate and a multi-layered light-shielding layer having non-transparent layers and transparent layers alternately laminated on the transparent substrate.

In an example embodiment, the multi-layered light-shielding layer may be patterned into multi-layered light-shielding patterns.

In an example embodiment, the non-transparent layers may be silicon layers and the transparent layers may be silicon oxide layers.

In an example embodiment, the non-transparent layer may be formed of an inorganic material containing silicon, or a metal selected from the group consisting of chromium, molybdenum, aluminum, titanium, tantalum, and ruthenium.

In an example embodiment, transparent layer may be formed of a silicon oxide.

In an example embodiment, the photomask may further include a capping layer on the multi-layered light-shielding patterns.

In an example embodiment, the capping layer may be formed of a metal selected from the group consisting of chromium, molybdenum, aluminum, titanium, and ruthenium, or a non-transparent inorganic material.

In an example embodiment, the multi-layered light-shielding patterns may be formed by randomly laminating at least three layers of two or more different kinds of non-transparent layers and a transparent layer.

In an example embodiment, the non-transparent layers and transparent layers may be laminated in pairs by an integer multiple N. For example, N may be greater than or equal to one.

In an example embodiment, the photomask may further include a chromium layer on the multi-layered light-shielding patterns.

In an example embodiment, the transparent substrate may be formed of one of glass and quartz.

In an example embodiment, the photomask may further include a photosensitive film on the light-shielding layer.

In an example embodiment, the non-transparent layer may be formed of an inorganic material containing silicon, or, alternatively, a metal selected from a group of chromium, molybdenum, aluminum, titanium, tantalum, and ruthenium.

In an example embodiment, the light-shielding layer may be formed by randomly laminating at least three layers of non-transparent and transparent layers.

In an example embodiment, the photomask may further include a capping layer between the light-shielding film and the photosensitive film.

According to example embodiments, a method of manufacturing a photomask may include laminating non-transparent layers and transparent layers alternately on a transparent substrate to form a light-shielding layer, forming a photosensitive film on the light-shielding layer, patterning the photosensitive film so as to form photosensitive film patterns, patterning the light-shielding layer using the photosensitive film patterns as an etching mask so as to form light-shielding patterns, and removing the photosensitive film patterns.

In an example embodiment, the light-shielding layer may have the non-transparent layers and transparent layers laminated in pairs by an integer multiple N, where N is greater than or equal to one.

In an example embodiment, the patterning of the non-transparent layer may be performed using gas containing a chlorine radical (Cl—) or a fluorine radical (F—).

In an example embodiment, the patterning of the transparent layer may be performed using gas containing a fluorine radical (F—), and carbon (C) or sulfur (S).

According to an example embodiment, a photomask may include a glass substrate, and multi-layered light-shielding patterns having non-transparent and transparent layers alternately laminated on the glass substrate.

The light-shielding patterns may have the non-transparent and transparent layers laminated in pairs by an integral multiple.

The light-shielding patterns may be formed by randomly laminating at least three layers of two or more different kinds of non-transparent layers and a transparent layer.

The non-transparent layer may be formed of an inorganic material containing silicon, or a metal selected from a group of chromium, molybdenum, aluminum, titanium, tantalum, and ruthenium.

The transparent layer may be formed of a silicon oxide.

A capping layer may be formed on the light-shielding patterns.

The capping layer may be formed of a metal selected from a group of chromium, molybdenum, aluminum, titanium, and ruthenium, or a non-transparent inorganic material.

According to example embodiments, a photomask may include a glass substrate, and multi-layered light-shielding patterns having silicon layers and silicon oxide layers laminated in pairs by an integral multiple on the glass substrate.

A chromium layer may be formed on the light-shielding patterns.

According to example embodiments, a method of manufacturing a photomask may include preparing a glass substrate, forming a light-shielding layer having non-transparent and transparent layers laminated on the glass substrate, forming a photosensitive film on the light-shielding layer, patterning the photosensitive film so as to form photosensitive film patterns, patterning the light-shielding layer using the photosensitive film patterns as an etching mask so as to form light-shielding patterns, and removing the photosensitive film patterns.

The light-shielding layer may have the non-transparent and transparent layers laminated of an integer multiple.

The non-transparent layer may be formed of an inorganic material containing silicon, or a metal selected from a group of chromium, molybdenum, aluminum, titanium, tantalum, and ruthenium.

The transparent layer may be formed of a silicon oxide.

A capping layer may be formed on the light-shielding layer and then patterned.

The capping layer may be formed of a metal selected from a group of chromium, molybdenum, aluminum, titanium, tantalum, and ruthenium, or a non-transparent inorganic material.

Patterning of the non-transparent layer may be performed using gas containing a chlorine radical (Cl—) or a fluorine radical (F—), and patterning of the transparent layer may be performed using gas containing a fluorine radical (F—) and carbon (C) or sulfur (S).

According to example embodiments, a blank photomask may include a glass substrate, a light-shielding film having non-transparent and transparent layers alternately laminated on the glass substrate, and a photosensitive film that is formed on the light-shielding film.

The light-shielding film may have the non-transparent and transparent layers of an integer multiple.

The non-transparent layer may be formed of an inorganic material containing silicon, or a metal selected from a group of chromium, molybdenum, aluminum, titanium, tantalum, and ruthenium.

The transparent layer may be formed of a silicon oxide.

The light-shielding film may be formed by randomly laminating at least three layers of non-transparent and transparent layers.

A capping layer may be formed between the light-shielding film and the photosensitive film.

The capping layer may be formed of a metal selected from a group of chromium, molybdenum, aluminum, titanium, tantalum, and ruthenium, or a non-transparent inorganic material.

According to example embodiments, a blank photomask may include a glass substrate, a multi-layered light-shielding film having silicon layers and silicon oxide layers of an integer multiple on the glass substrate, and a photosensitive film that is formed on the light-shielding film.

A chromium layer may be formed between the light-shielding film and the photosensitive film.

### BRIEF DESCRIPTION OF THE DRAWINGS

Example embodiments will become more apparent by describing them in detail with reference to the attached drawings, in which:

FIGS. 1A to 1E are cross-sectional views schematically showing photomasks, according to example embodiments;

FIG. 2 is a graph showing aerial images of the photomasks, according to example embodiments;

FIG. 3 is a graph showing aerial images of the photomasks, according to example embodiments;

FIGS. 4A to 4G are cross-sectional views schematically illustrating a method of manufacturing a photomask, according to example embodiments;

FIGS. 5A and 5B are cross-sectional views schematically showing blank photomasks, according to example embodiments;

FIGS. 6A to 6D are cross-sectional views schematically showing photomasks, according to example embodiments; and

FIGS. 7A and 7B are cross-sectional views schematically showing blank photomasks, according to example embodiments.

### DESCRIPTION OF EXAMPLE EMBODIMENTS

Advantages and features of example embodiments and methods of accomplishing the same may be understood more readily by reference to the following detailed description of example embodiments and the accompanying drawings. Example embodiments may, however, be embodied in many different forms and should not be construed as being limited to the embodiments set forth herein. Rather, these example embodiments are provided so that this disclosure will be thorough and complete and will fully convey the concept of the present invention to those skilled in the art, and the present invention will only be defined by the appended claims. The scale of each layer or each region has been adjusted in order to have a recognizable size in the drawings. Like reference numerals refer to like elements throughout the specification.

Detailed illustrative embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

It will be understood that if an element or layer is referred to as being “on,” “against,” “connected to” or “coupled to” another element or layer, then it can be directly on, against connected or coupled to the other element or layer, or intervening elements or layers may be present. In contrast, if an element is referred to as being “directly on”, “directly connected to” or “directly coupled to” another element or layer, then there are no intervening elements or layers present. Like numbers refer to like elements throughout. As used herein, the term “and/or” includes any and all combinations of one or more of the associated listed items.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer or section from another region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

In the specification, example embodiments will be described with reference to plan and cross-sectional views, which are ideal schematic views. These views may be modified by a manufacturing technique and/or a tolerance. Therefore, example embodiments are not limited to those shown in the drawings but include changes which are made according to a manufacturing process. In the drawings, regions are schematically shown. The shapes of the regions shown in the drawings are illustrative specific device regions, but are not intended to limit the scope of example embodiments.

In example embodiments, light refers to light to be used to transfer patterns onto semiconductor wafers using photomasks. For example, light may include ultra violet light (UV), i-line, KrF excimer laser light, ArF excimer laser light, and so on. Therefore, transparency or a transparent layer indicates that said transparent layer is transparent to light. Further, non-transparency or a non-transparent layer indicates non-transparency to light.

In the specification, exposure indicates not only exposure to light, but also writing patterns. That is, when patterns are formed using electron beams, the electron beams are irradiated along the shapes of patterns to be formed by an electron gun, which produces the electron beams.

Hereinafter, photomasks including multi-layered light-shielding patterns, methods of manufacturing the same, and blank photomasks, according to example embodiments, will be described with reference to the accompanying drawings.

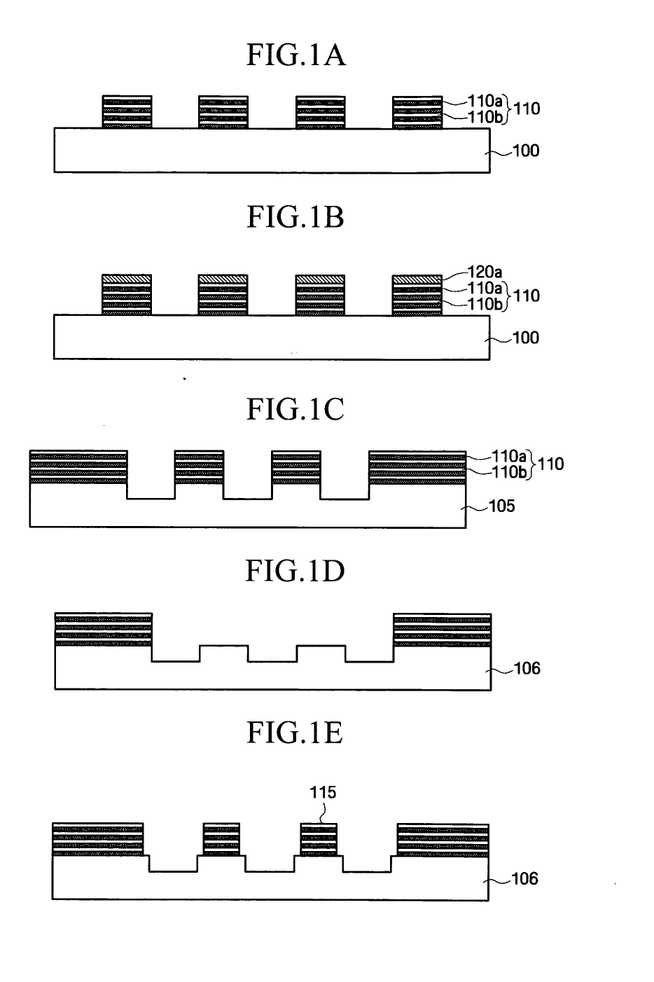

FIGS. 1A to 1E are cross-sectional views schematically showing photomasks including multi-layered light-shielding patterns, according to example embodiments.

Referring to FIG. 1A, a photomask, according to an example embodiment, may include multi-layered light-shielding patterns 110. The multi-layered light-shielding patterns 110 may have non-transparent layers 110a (non-transparent to light) and transparent layers 110b (transparent to light) that are alternatively laminated on a glass substrate 100.

The multi-layered light-shielding patterns 110 may have non-transparent and transparent layers 110a and 110b of an integer multiple. For example, when the multi-layered light-shielding patterns 110 have two or more pairs of the non-transparent and transparent layers 110a and 110b, better effects may be obtained as compared with the photomask of the related art. Furthermore, when the non-transparent and transparent layers 110a and 110b are laminated on the basis of the integer multiple, the manufacturing process may be stabilized.

The non-transparent and transparent layers 110a and 110b may be alternately laminated in a complementary manner.

The multi-layered light-shielding patterns 110 may be formed to have a thickness of 40 to 4000 Å (angstroms). Because the light-shielding patterns are multi-layered, even if the thickness of individual layers is less than those layers of the related art, the layer quality may be stabilized and a light-shielding effect may be improved.

The non-transparent layer 110a may be formed of a non-transparent inorganic material containing silicon or a metal selected from a group of chromium, a chromium oxide, molybdenum, aluminum, titanium, tantalum, and ruthenium, or any other suitable non-transparent material.

The transparent layer 110b may be formed of a silicon oxide or any other suitable transparent material. For example, the silicon oxide may be at least one of a high-temperature wet oxide, SOG, USG, BSG, PSG, BPSG, and HSQ.

In example embodiments, the multi-layered structure of the non-transparent and transparent layers 110a and 110b may have a silicon layer and a silicon oxide layer or a metal layer and a silicon oxide layer, or simply a non-transparent layer and a transparent layer.

However, example embodiments are illustrative for selecting materials that may be easily used for experiments so as to implement the technical idea of the present invention, but are intended to limit the present invention. For instance, the materials described above, although easy to use in experimenting with example embodiments, are not the only materials which may be used to implement example embodiments.

Referring to FIG. 1B, a photomask, according to an example embodiment, may include multi-layered light-shielding patterns 120 which may be formed by alternately laminating non-transparent and transparent layers 110a and 110b on a glass substrate 100, and subsequently laminating a capping layer 120a on the uppermost layer.

The capping layer 120a may be formed of a metal selected from a group of chromium, molybdenum, aluminum, titanium, tantalum, and ruthenium, or a non-transparent inorganic material.

In an example embodiment, the capping layer 120a may be formed of chromium. Example embodiments may also be illustrative for the sake of selecting a material that may be easily used for experiments so as to implement the technical idea of the invention, but is not intended to limit the present invention.

The photomask shown in FIG. 1B may be obtained by a relatively stable manufacturing process compared with the photomask shown in FIG. 1A.

When a metal layer, such as chromium, is used as the capping layer 120a, with high etching selectivity between the capping layer 120a and the multi-layered light-shielding layer 110, a process for forming the multi-layered light-shielding patterns 110 may be stabilized. When the capping layer 120a is removed after the multi-layered light-shielding patterns 110 are formed, the photomask having the structure shown in FIG. 1A may be obtained.

Referring to FIG. 1C, in a photomask according to an example embodiment, a glass substrate 105, in which the light-shielding patterns 110 are not formed, may be selectively etched, such that a substrate etching type photomask is obtained.

Referring to FIG. 1D, in a photomask according to an example embodiment, regions of a substrate where patterns are to be formed may be etched, such that a CPSM or a substrate etching type PSM is obtained.

Referring to FIG. 1E, in a photomask according to an example embodiment, multi-layered light-shielding patterns 115 may be formed in regions of a non-etched glass substrate for a CPSM such that the areas of the patterns are smaller than the top area of the glass substrate. As a result, a rim type PSM may be obtained. The photomask shown in FIG. 1E may be particularly useful when minute contact holes are formed.

The photomasks according to example embodiments, for example those shown in FIGS. 1A to 1E, may use silicon or chromium as the non-transparent layer 110a. Silicon or chromium is illustrative for a material that may be easily used for experiments so as to implement the technical idea of the present invention, but is not intended to limit the present invention.

A result of observation of various photomasks according to the related art for a long time is that haze is frequently formed in case of a photomask using MoSiON. It has been seen through multiple experiments that Mo/Si-based compounds are vulnerable to the haze defect. In contrast, with silicon, silicon oxide, chromium, or the like, it can be seen that the frequency of haze is low. Therefore, in example embodiments, photomasks may be manufactured using silicon, silicon oxide, chromium, or the like, not the Mo/Si compound.

As a result of experiments, the photomasks according to example embodiments may relatively rarely generate the haze defect.

In addition, the photomasks according to example embodiments may provide better resolution compared to the photomask using Mo/Si-based compounds.

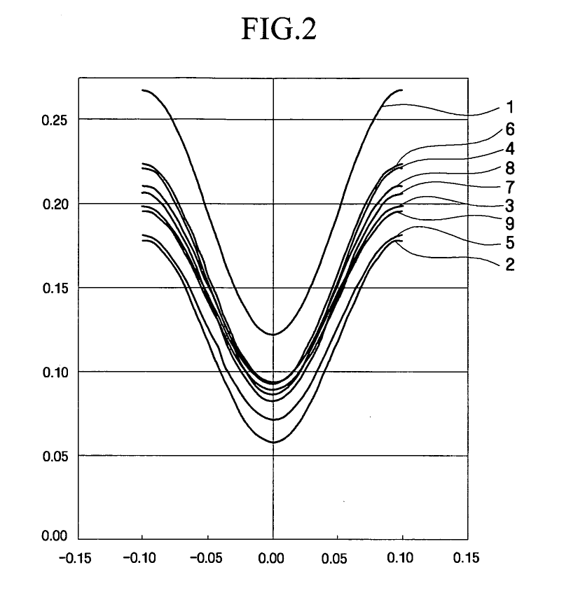

FIG. 2 is a graph showing aerial images that may be obtained through comparison and experiments of resolution between photomasks according to the related art and the photomasks according to example embodiments. In particular, contrast corresponding to pattern resolution of each photomask is shown. The X axis represents position, and the Y axis represents intensity of light transmitting through the photomask. The contrast may be calculated according to the following equation:

(maximum intensity−minimum intensity)/(maximum intensity+minimum intensity)=

(Imax−Imin)/(Imax+Imin)

The photomasks according to example embodiments, which are used in the experiments of FIG. 2, may include multi-layered light-shielding patterns formed by laminated one, two, four, and/or eight pairs of silicon layers and silicon oxide layers, respectively.

In addition, an experiment is made on an example where a capping layer is formed on the light-shielding patterns.

Table 1 shows the calculation and experiment results of the aerial images of the photomasks according to the related art and the photomasks according to example embodiments using contrast values.

TABLE 1
Contrast Values for Different Patterns (Experimental Results)

| | Light-Shielding Pattern | Pattern Thickness (Å) | Contrast |
|---|---|---|---|
| 1 | Cr binary (Related Art) | 700 | 0.33 |
| 2 | Mo/Si PSM (Related Art) | 920 | 0.5 |
| 3 | Cr/SiO₂ (Related Art) | 700/1800 | 0.39 |
| 4 | One pair of Si/SiO₂ | 1000/1000 | 0.45 |
| 5 | Two pairs of Si/SiO₂ | (250/250) × 2 | 0.49 |
| 6 | Four pairs of Si/SiO₂ | (125/125) × 4 | 0.43 |
| 7 | Eight pairs of Si/SiO₂ | (62.5/62.5) × 8 | 0.42 |
| 8 | Eight pairs of Si/SiO₂ + Cr | {(62.5/62.5) × 8} + 700 | 0.40 |
| | capping layer | | |
| 9 | Si/SiO₂ | 700/1800 | 0.34 |

Specified experimental conditions are as follows. An Off-Axis illumination (OAI) method using an annular type aperture is performed. Here, the annular aperture has a numerical aperture (NA) of 0.8, an inner diameter of 0.72%, and an outer diameter of 0.92%. The aerial images of the individual photomasks are formed using dark patterns having a width of 0.1 μm.

Referring to FIG. 2 and Table 1, the Cr binary photomask has the lowest contrast of about 0.3. The transmittance attenuating PSM has the highest contrast of about 0.5.

However, each of the photomasks according to example embodiments has a contrast relatively higher than the transmittance attenuating PSM using Mo/Si. Most of the photomasks show the contrast of 0.4 or more. In particular, a photomask according to an example embodiment, in which the multi-layered light-shielding patterns are formed of two pairs of Si/SiO2, has a contrast of about 0.49. Therefore, it is understood that the photomask according to an example embodiment may be relatively better than the transmittance attenuating PSM using Mo/Si.

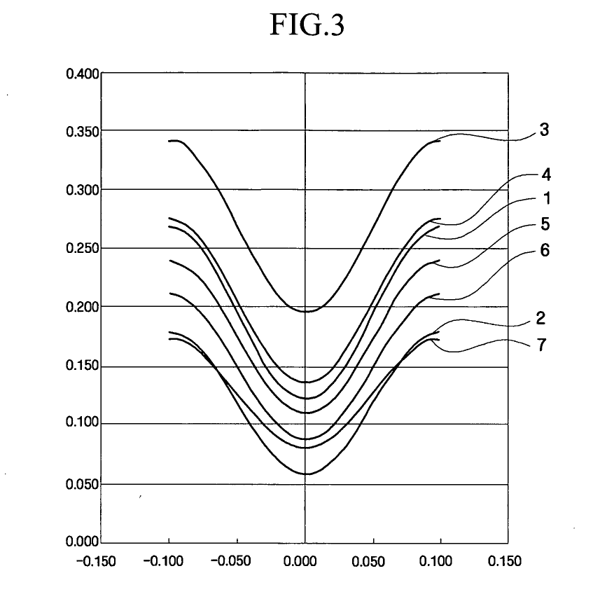

FIG. 3 shows the comparison and experiment results between photomasks according to the related art and photomasks using chromium as a non-transparent layer, according to example embodiments.

The photomasks according to example embodiments used in the experiment of FIG. 3, may include multi-layered light-shielding patterns formed by laminating one, two, four and/or eight pairs of chromium layers and silicon oxide layers, respectively. The experiment was performed in a state where the multi-layered patterns formed by alternately laminating the chromium layers and the silicon oxide layers (Cr/SiO2) have a fixed thickness of about 400 Å. Experimental results are shown in Table 2:

TABLE 2
Contrast Values for Different Patterns (Experimental Results)

| | Light-Shielding Pattern | Contrast (Approximate Value) |
|---|---|---|
| (1) | Cr (Related art) | 0.36 |
| (2) | Mo/Si (Related art) | 0.5 |
| (3) | One pair of Cr/SiO₂ | 0.27 |
| (4) | Two pairs of Cr/SiO₂ | 0.325 |
| (5) | Three pairs of Cr/SiO₂ | 0.40 |
| (6) | Four pairs of Cr/SiO₂ | 0.42 |
| (7) | Eight pairs of Cr/SiO₂ | 0.43 |

Referring to FIG. 3 and Table 2, it is understood that the more chromium and silicon oxide layers are multi-layered, the higher the contrast may be obtained. Furthermore, it is understood that the thicker the multi-layered patterns are, the higher the contrast may be obtained.

The results shown in FIGS. 2 and 3 show that the photomasks according to example embodiments may have resolution superior to the photomasks according to the related art.

In the experiments of FIGS. 2 and 3, the non-transparent layer and the transparent layer of the photomask including the multi-layered light-shielding patterns according to example embodiments have the same thickness. However, this is illustrative for the sake of simplifying a manufacturing process, but is not intended to be limiting.

The non-transparent layer and the transparent layer are not limited to have a certain thickness and are not formed according to a particular relationship there between. That is, when the multi-layered light-shielding pattern has a thickness of 2000 Å, each of the non-transparent and transparent layers does not need to have a thickness of 1000 Å. The non-transparent layer and transparent layer may be formed to have the thicknesses of 500 Å and 1500 Å, or 1500 Å and 500 Å, respectively.

In the experiment of FIG. 2, the photomasks according to example embodiments may have the same total thickness of the multi-layered light-shielding pattern. However, the photomasks do not necessarily have to have the same total thickness.

If the experiment is made while changing the thickness of the multi-layered light-shielding pattern of the photomasks, optimum results may be obtained.

The photomasks including the multi-layered light-shielding patterns according to example embodiments may be manufactured in high yield, because the alternately laminated non-transparent and transparent layers complement causes for defects that may occur during a process. Therefore, even though the photomasks of example embodiments may be thinner than those in the related art, the shapes of patterns can be stably kept in the photomasks of example embodiments. In an example with a single layer, an etching process or a cleaning process may cause damage, and the damage may be large or relatively large. In contrast, in example embodiments, the patterns are multi-layered thus damage may be suppressed.

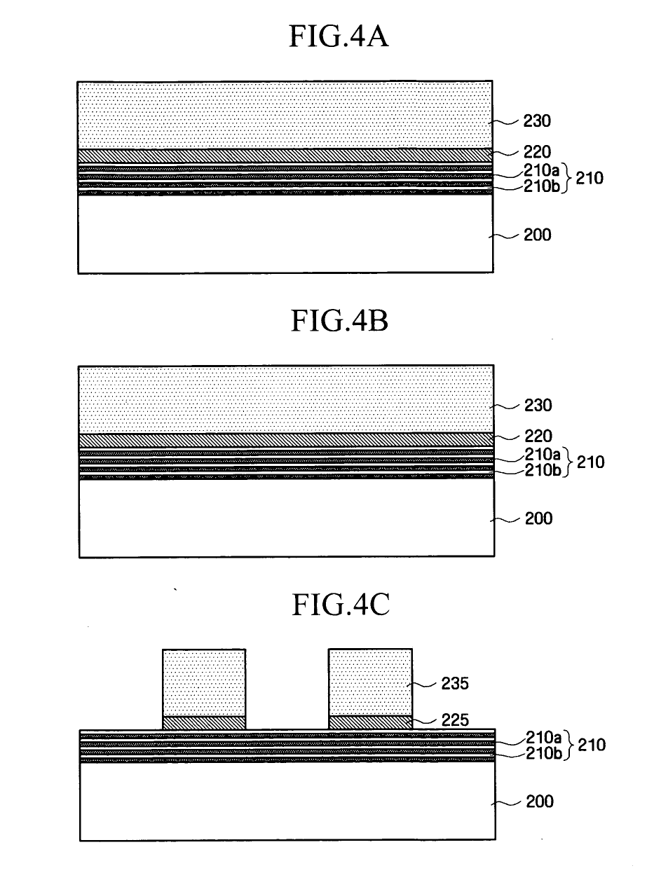

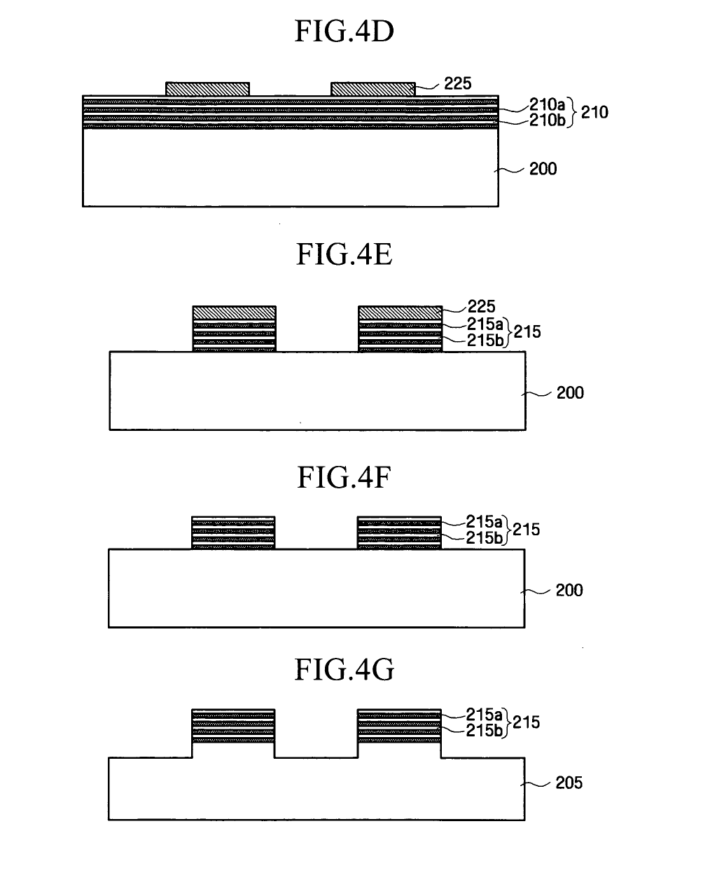

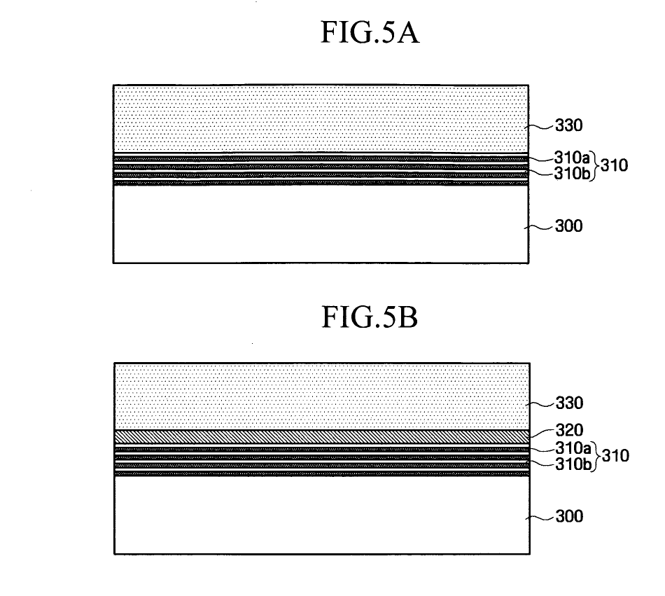

FIGS. 4A to 4G are cross-sectional views schematically illustrating a method of manufacturing a photomask including a multi-layered shielding layer, according to example embodiments.

Referring to FIG. 4A, a light-shielding layer 210 formed by alternately laminating non-transparent and transparent layers 210a and 210b may be formed on a glass substrate 200, a capping layer 220 is formed on the light-shielding layer 210, and a photosensitive film 230 is formed on the capping layer 220.

For example, the glass substrate 200 may be a quartz substrate.

The non-transparent layer 210a may be formed of a non-transparent inorganic material containing silicon, or a metal selected from the group consisting of chromium, chromium oxide, molybdenum, titanium, tantalum, and ruthenium. The non-transparent layer 210a may be formed of one material among these materials or may be formed of two or more materials selected from the materials. In an example embodiment, the non-transparent layer 210a may be formed of silicon.

The non-transparent layer 210b may be formed of a silicon oxide. For example, the transparent layer 210b may be formed of at least one of a high-temperature wet oxide, SOG, USG, BSG, PSG, BPSG, and HSQ.

The capping layer 220 may be formed of a non-transparent inorganic material, or a metal selected from a group consisting of chromium, molybdenum, aluminum, titanium, tantalum, and ruthenium. Since chromium is a known material for photomasks, a process for processing chromium is relatively easy. Therefore, chromium may be relatively easily used as the capping layer 220.

A photosensitive film, which may react to a light source, may be used as the photosensitive film 230. Since electron beams may be used as an exposure source in example embodiments, an electron beam resist may be used.

Referring to FIG. 4B, the photosensitive film 230 may be exposed to electron beams and developed so as to form photosensitive film patterns 235. A technique of forming the photosensitive film patterns 235 by the exposure and development using electron beams is well known in the art, and thus the detailed description thereof will be omitted herein for the sake of brevity.

Referring to FIG. 4C, the capping layer 220 may be patterned using the photosensitive film patterns 235 as an etching mask so as to form capping layer patterns 225.

Because the capping layer 220 may be formed of chromium, which is a metal, the capping layer 220 may be patterned by a mixed gas containing a chlorine radical (Cl—) or a fluorine radical (F—). For example, a mixed gas consisting of Cl₂, BCl₃, SiCl₄, HBr, or the like may be used. Meanwhile, the capping layer 220 may be patterned by an acid etchant, such as nitric acid or any other suitable etchant. The mixed gas or the metal etchant, which may be used to pattern a metal, is well known in the art, and thus detailed description thereof will be omitted herein for the sake of brevity.

FIG. 4D depicts a state where the photosensitive film patterns 235 are removed. The photosensitive film patterns 235 may be removed by a dry removing method using O₂ gas or a wet removing method using H₂SO₄. The method of removing the photosensitive film patterns 235 is also well known in the art, and thus detailed description thereof will be omitted.

Referring to FIG. 4E, the light-shielding layer 210 may be patterned using the capping layer patterns 225 as an etching mask so as to form multi-layered light-shielding patterns 215.

According to an example embodiment, in a method of forming the multi-layered light-shielding patterns 215, the light-shielding layer 210 may be patterned by alternately using a mixed gas containing a chlorine radical (Cl—) or a fluorine radical (F—) and a mixed gas containing a fluorine radical (F—) and carbon (C) or sulfur (S).

For example, the non-transparent layer 215a may be formed of silicon and a mixed gas of HBr, Cl₂, CClF₃, CCl₄, SF₆, or the like may be used. The non-transparent layer 215a may be formed of a metal, such as chromium, and a mixed gas of Cl₂, BCl₃, SiCl₄, HBr, or the like may be used. A mixed gas of SF₆, C₂F₆, Cl₂, or the like may be also used in example embodiments.

For example, the transparent layer 215b may be formed of a silicon oxide, and a mixed gas of CF₄, CHF₃, C₂F₆, or the like may be used.

Furthermore, Ar or O2 gas may be added to the mixed gas.

Any other method of forming the multi-layered light-shielding patterns 215, which is a well known technique in the art, instead of the above-described method, may be applied, and thus further description thereof will be omitted.

Referring to FIG. 4F, the capping layer patterns 225 may be removed so as to complete the photomask including the multi-layered light-shielding patterns 215 shown in FIG. 1A, according to an example embodiment.

The photomask shown in FIG. 1B, according to an example embodiment, may be completed, without removing the capping layer patterns 225.

Referring to FIG. 4G, a photomask according to an example embodiment may be manufactured by etching a glass substrate 205. The photomask manufacture in such a manner may exhibit the same effects as those in the CPSM.

In an example embodiment, a step of etching a substrate may be performed before the capping layer patterns 225 are removed.

FIGS. 5A and 5B are cross-sectional views schematically showing blank photomasks, according to example embodiments.

Referring to FIG. 5A, a blank photomask according to an example embodiment may include a multi-layered light-shielding layer 310 having non-transparent and transparent layers 310a and 310b alternately laminated on a glass substrate 300, and a photosensitive film 330 that may be formed on the uppermost layer. The photosensitive film may be an electron beam resist.

The light-shielding layer 310 may be formed by alternately laminating the non-transparent and transparent layers 310a and 310b. In an example embodiment, the non-transparent and transparent layers 310a and 310b may be laminated in pairs by an integer multiple N. For example, N may be greater than or equal to one.

The light-shielding layer 310 may be formed to have a thickness of 40 to 4000 Å.

The non-transparent layer 310a may be formed of a non-transparent inorganic material containing silicon, or a metal selected from the group consisting of chromium, chromium oxide, molybdenum, aluminum, titanium, tantalum, and ruthenium.

The transparent layer 310b may be formed of silicon oxide, and for example, at least one of a high-temperature wet oxide, SOG, USG, BSG, PSG, BPSG, and HSQ.

The light-shielding layer 310 may be formed by randomly laminating at least three layers of the non-transparent and transparent layers 310a and 310b.

A capping layer 320 may be formed between the light-shielding layer 310 and the photosensitive film 330.

The capping layer 320 may be formed of a metal selected from the group consisting of chromium, molybdenum, aluminum, titanium, and ruthenium, or for example, a non-transparent inorganic material.

Blank photomasks according to example embodiments (e.g., FIGS. 5A and 5B) may be suitable for manufacturing the photomasks including the multi-layered light-shielding patterns according to example embodiments.

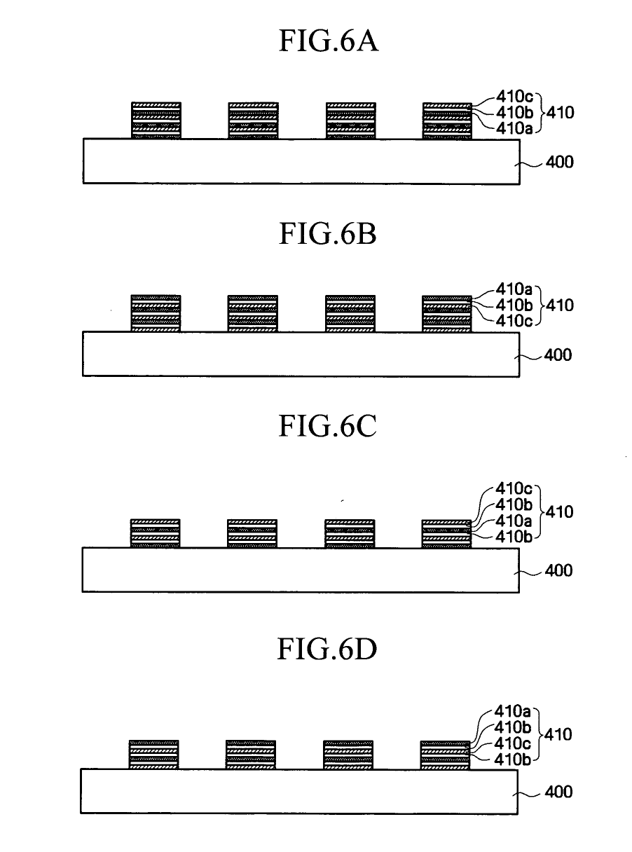

FIGS. 6A to 6D are cross-sectional views schematically showing photomasks including the multi-layered light-shielding patterns, according to example embodiments.

Referring to FIGS. 6A to 6D, each of the photomasks according to example embodiments may include multi-layered light-shielding patterns 410 having three or more kinds of layers 410a, 410b, and 410c laminated on a glass substrate 400.

The non-transparent layers 410a and 410c may be formed of at least two materials selected from a group of molybdenum, aluminum, titanium, tantalum, and ruthenium, and a non-transparent inorganic material, as well as silicon and chromium.

The transparent layer 410b may be formed of a silicon oxide, and for example, at least one of a high-temperature wet oxide, SOG, USG, BSG, PSG, BPSG, and HSQ.

Referring to FIGS. 6A to 6D, a silicon layer or a chromium layer may be formed as the non-transparent layers, and a silicon oxide layer may be formed as a transparent layer. In an example embodiment, the silicon layer or chromium layer and the silicon oxide layer may be alternately formed. Because the multi-layered light-shielding pattern 410 may be formed of three or more kinds of layers, a manufacturing process may be simplified, and patterning capability may be stabilized.

For example, if the layers 410a, 410b, and 410c are formed of silicon, silicon oxide, and chromium, respectively, they may be laminated in an order of silicon, silicon oxide, and chromium, as shown in FIG. 6A or in an order of chromium, silicon oxide, and silicon, as shown in FIG. 6B. Furthermore, the layers 410a, 410b, and 410c may be laminated in an order of silicon, silicon oxide, chromium, and silicon oxide, as shown in FIG. 6C or may be laminated in an order of chromium, silicon oxide, silicon, and silicon oxide, as shown in FIG. 6D.

Example embodiments as shown in FIGS. 6A to 6D are illustrative for ease of understanding of the technical ideas embodied therein, but are not intended to limit the present application. According to the technical ideas, though not shown in FIGS. 6A to 6D, the multi-layered light-shielding patterns may be formed by randomly laminating various kinds of non-transparent layers and transparent layers. Accordingly, when another material or a silicon oxide of a different kind, instead of a silicon oxide, may be used as the transparent layer 410b, the transparent layers 410b may be repeatedly laminated.

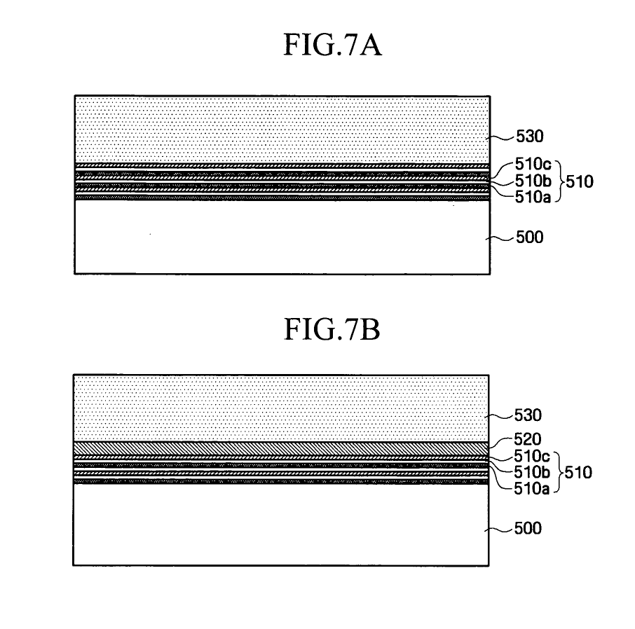

FIGS. 7A and 7B are cross-sectional views schematically showing blank photomasks, according to example embodiments.

Referring to FIG. 7A, each of the blank photomasks may include a multi-layered light-shielding layer 510 that may be formed by randomly laminating at least three layers of different non-transparent layers 510a and 510c and a transparent layer 510b on a glass substrate 500, and a photosensitive film 530 may be formed on the uppermost layer. For example, the photosensitive film may be an electron beam resist.

The non-transparent layers 510a and 510c may be formed of two or more materials of a non-transparent inorganic material containing silicon and a metal selected from a group of chromium, a chromium oxide, molybdenum, aluminum, titanium, tantalum, and ruthenium.

The transparent layer 510b may be formed of a silicon oxide, and particularly, at least one of a high-temperature wet oxide, SOG, USG, BSG, PSG, BPSG, and HSQ.

Referring to FIG. 7B, a capping layer 520 may be formed between the multi-layered shielding layer and the photosensitive film.

The capping layer 520 may be formed of one or more metal materials selected from the group consisting of chromium, molybdenum, aluminum, titanium, tantalum, and ruthenium.

Blank photomasks according to example embodiments shown in FIGS. 7A to 7B may be suitable for manufacturing photomasks including multi-layered light-shielding patterns according to example embodiments as shown in FIGS. 6A to 6D.

As described above, photomasks including the multi-layered light-shielding patterns according to example embodiments may have few defects and high resolution, thereby stabilizing a semiconductor manufacturing process.

Although example embodiments have been described in connection with the attached drawings, it will be apparent to those skilled in the art that various modifications and changes may be made thereto without departing from the sprit and scope set forth therein. Therefore, it should be understood that the above example embodiments are not limitative, but illustrative in all aspects. For example, particular embodiments have been described with reference to a glass substrate. It will be understood that alternatively any suitable transparent substrate may be used, for example, a quartz or fused silica substrate.

What is claimed is:

1. A photomask comprising:
a transparent substrate; and
a multi-layered light-shielding layer having non-transparent layers and transparent layers alternately laminated on the transparent substrate.

2. The photomask of claim 1, wherein the multi-layered light-shielding layer is patterned into multi-layered light-shielding patterns.

3. The photomask of claim 2, wherein:
the non-transparent layers are silicon layers; and
the transparent layers are silicon oxide layers.

4. The photomask of claim 2, wherein the non-transparent layer is formed of an inorganic material containing silicon, or a metal selected from the group consisting of chromium, molybdenum, aluminum, titanium, tantalum, and ruthenium.

5. The photomask of claim 2, wherein the transparent layer is formed of a silicon oxide.

6. The photomask of claim 2, further comprising a capping layer on the multi-layered light-shielding patterns.

7. The photomask of claim 6, wherein the capping layer is formed of a metal selected from the group consisting of chromium, molybdenum, aluminum, titanium, and ruthenium, or a non-transparent inorganic material.

8. The photomask of claim 2, wherein the multi-layered light-shielding patterns are formed by randomly laminating at least three layers of two or more different kinds of non-transparent layers and a transparent layer.

9. The photomask of claim 2, wherein the non-transparent layers and transparent layers are laminated in pairs by an integer multiple N, where N is greater than or equal to one.

10. The photomask of claim 9, wherein:
the non-transparent layers are silicon layers; and
the transparent layers are silicon oxide layers.

11. The photomask of claim 9, further comprising a chromium layer on the multi-layered light-shielding patterns.

12. The photomask of claim 1, wherein the transparent substrate is formed of one of glass and quartz.

13. The photomask of claim 1, further comprising a photosensitive film on the light-shielding layer.

14. The photomask of claim 13, wherein the light-shielding layer has the transparent and transparent layers laminated in pairs by an integer multiple N, where N is greater than or equal to one.

15. The photomask of claim 13, wherein the non-transparent layer is formed of an inorganic material containing silicon, or a metal selected from a group of chromium, molybdenum, aluminum, titanium, tantalum, and ruthenium.

16. The photomask of claim 13, wherein the transparent layer is formed of silicon oxide.

17. The photomask of claim 13, wherein the light-shielding layer is formed by randomly laminating at least three layers of non-transparent and transparent layers.

18. The photomask of claim 13, further comprising a capping layer between the light-shielding film and the photosensitive film.

19. The blank photomask of claim 18, wherein the capping layer is formed of a metal selected from the group consisting of chromium, molybdenum, aluminum, titanium, tantalum and ruthenium, or a non-transparent inorganic material.

20. The photomask of claim 13, wherein:
the non-transparent layers are silicon layers; and
the transparent layers are silicon oxide layers.

21. The photomask of claim 20, wherein a chromium layer is formed between the light-shielding layer and the photosensitive film.

22. A method of manufacturing a photomask, the method comprising:
laminating non-transparent layers and transparent layers alternately on a transparent substrate to form a light-shielding layer;
forming a photosensitive film on the light-shielding layer;
patterning the photosensitive film so as to form photosensitive film patterns;
patterning the light-shielding layer using the photosensitive film patterns as an etching mask so as to form light-shielding patterns; and
removing the photosensitive film patterns.

23. The method of claim 22, wherein the light-shielding layer has the non-transparent layers and transparent layers laminated in pairs by an integer multiple N, where N is greater than or equal to one.

24. The method of claim 22, wherein the non-transparent layers are formed of an inorganic material containing silicon, or a metal selected from the group consisting of chromium, molybdenum, aluminum, titanium, tantalum, and ruthenium.

25. The method of claim 22, wherein the transparent layers are formed of silicon oxide.

26. The method of claim 22, further comprising forming a capping layer on the light-shielding layer.

27. The method of claim 26, wherein the capping layer is formed of a metal selected from the group consisting of chromium, molybdenum, aluminum, titanium, tantalum, and ruthenium, or a non-transparent inorganic material.

28. The method of claim 22, wherein:
patterning of the non-transparent layer is performed using gas containing a chlorine radical (Cl—) or a fluorine radical (F—); and
patterning of the transparent layer is performed using gas containing a fluorine radical (F—), and carbon (C) or sulfur (S).
